(19) United States
(12) Patent Application Publication
(10) Pub. No.: US 2021/0311818 A1
(43) Pub. Date: Oct. 7, 2021

(54) RUNTIME POST PACKAGE REPAIR FOR DYNAMIC RANDOM ACCESS MEMORY

(71) Applicant: INTEL CORPORATION, Santa Clara, CA (US)

(72) Inventors: Vincent Zimmer, Federal Way, WA (US); Anil Agrawal, Santa Clara, CA (US); Dujian Wu, Shanghai (CN); Shijian Ge, Shanghai (CN); Zhenglong Wu, Shanghai (CN)

(73) Assignee: INTEL CORPORATION, Santa Clara, CA (US)

(21) Appl. No.: 17/255,109

(22) PCT Filed: Dec. 11, 2018
(86) PCT No.: PCT/CN2018/120199

§ 371 Date: Dec. 22, 2020

(51) Int. Cl. G06F 11/07

(52) U.S. Cl. CPC G06F 11/0793; G11C 11/401; G06F 11/0751; G06F 11/073

(57) ABSTRACT

Systems, apparatuses and methods may provide for technology that handles failures in memory hardware (e.g., dynamic random access memory (DRAM)) via runtime post package repair. Such technology may include operations to perform a runtime post package repair in response to a memory hardware failure detected in the memory. In such an example, the runtime post package repair may be done after power up boot operations have been completed.

### TECHNICAL FIELD

Embodiments generally relate to thread scheduling in computing systems. More particularly, embodiments relate to technology that handles failures in memory hardware (e.g., dynamic random access memory (DRAM)) via runtime post package repair.

### BACKGROUND

Errors in dynamic random access memory (DRAM) are a common form of hardware failure in modern compute clusters. Failures are often costly both in terms of hardware replacement cost and service disruption. Both end users and original equipment manufacturers (OEMs) may place a high demand on effective memory error handling.

### BRIEF DESCRIPTION OF THE DRAWINGS

The various advantages of the embodiments will become apparent to one skilled in the art by reading the following specification and appended claims, and by referencing the following drawings, in which:

FIG. 1 is an illustration of an example of a runtime memory repair system according to an embodiment;

FIG. 2 is a block diagram of an example of a memory device adapted for runtime memory repair according to an embodiment;

FIG. 3 is an illustration of an example of a procedure for runtime post package repair according to an embodiment;

FIG. 4 is an illustration of an example of a procedure for power up post package repair, which is a different solution for memory repair as compared to the runtime post package repair disclosed herein;

FIG. 5 is a flowchart of an example of a method of repairing runtime memory according to an embodiment;

FIG. 6 is a more detailed flowchart of an example of a method repairing runtime memory according to an embodiment;

FIG. 7 is a block diagram of an example of a computing system that includes a system on chip according to an embodiment;

FIG. 8 is an illustration of an example of a semiconductor apparatus according to an embodiment;

FIG. 9 is a block diagram of an example of a processor according to an embodiment; and

FIG. 10 is a block diagram of an example of a multi-processor based computing system according to an embodiment.

### DESCRIPTION OF EMBODIMENTS

As described above, errors in dynamic random access memory (DRAM) are a common form of hardware failure in modem compute clusters. Failures are costly both in terms of hardware replacement cost and service disruption. Both end users and original equipment manufacturers (OEMs) may place a high demand on effective memory error handling.

As will be described in greater detail below, some of the implementations described herein may adapt post package repair (PPR) procedures to conduct runtime repairs of memory hardware (e.g., DRAM) failures. Such runtime post package repair (PPR) procedures may advantageously operate without capacity loss, performance impact, and/or cost implication.

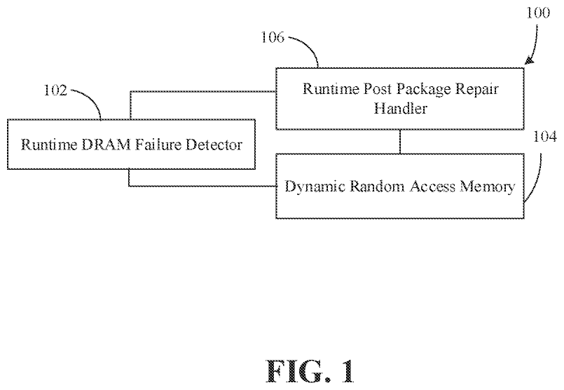

FIG. 1 is an illustration of an example of a runtime memory repair system 100 according to an embodiment. As illustrated, runtime memory repair system 100 may include a memory device such as, for example, a DRAM 104, a runtime DRAM failure detector 102, and runtime post package repair handler 106.

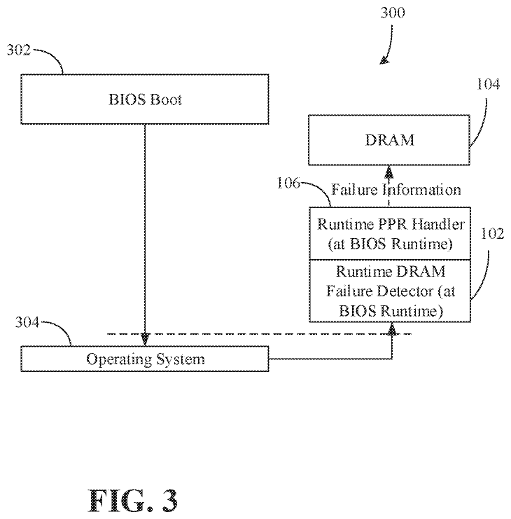

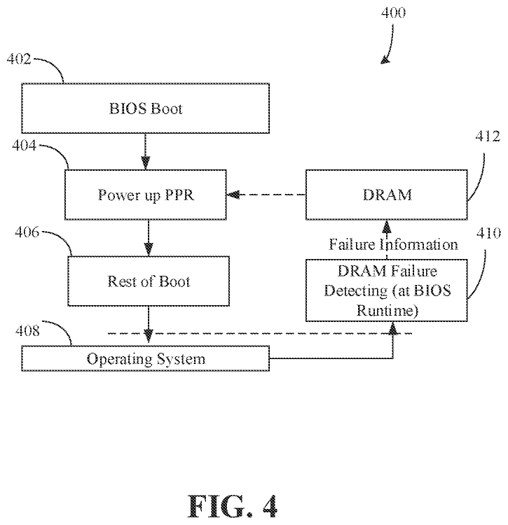

Some implementations described herein may provide for technology that detects hardware failures in the DRAM 104 via the runtime DRAM failure detector 102. In an embodiment, the runtime post package repair handler 106 corrects the detected hardware failures in the DRAM 104. In such an example, the runtime post package repair handler 106 may perform such corrections after power up boot operations have been completed. Conversely, post package repair may often be performed during power up operations (as illustrated below in FIG. 4) as opposed to during runtime operations (as illustrated below in FIG. 3).

For example, such a power up post package repair will typically adversely impact system availability because computing system will need to reset, as illustrated below in FIG. 4. In some examples, Error Correcting Code (ECC) memory is typically used for detecting and correcting system errors, for keeping system ECC capability and system performance (e.g., ECC may impact memory latency). Some implementations herein may provide a new methodology to repair the DRAM hardware failure at runtime via post package repair operations, as illustrated below in FIG. 3, which may avoid performance and memory capacity impact. For example, in the runtime environment, a memory error corrected by post package repair operations might be detected via a Double Data Rate (DDR) memory logic analyzer (LA) monitoring a DDR memory bus.

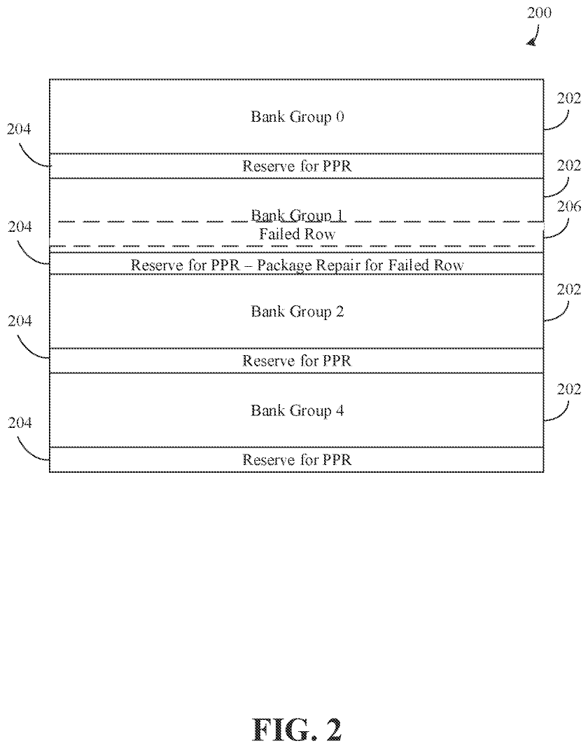

FIG. 2 is a block diagram of an example of a memory device 200 adapted for to runtime memory repair according to an embodiment. As illustrated, the memory device 200 may represent a dynamic random access memory (DRAM). In an embodiment, the memory device 200 includes a plurality of bank groups 202 (e.g., bank group 0, 1, 2, 4, etc.). Each of the plurality of bank groups 202 may include an associated reserve row 204, where each reserve row is be set aside to be used for runtime post package repair operations.

For example, when a failed row 206 is detected, the data in the failed row 206 may be corrected and saved to the reserve row 204 associated with the corresponding bank groups 202 (e.g., bank group 1, as illustrated here). As will be described in greater detail below, the failed row 206 may be repaired via post package repair operations. The corrected and saved failed row data may then be moved back to the now-repaired row of failed row 206.

Table 1 illustrates the limitations of other options for dealing with hardware failures in DRAM:

TABLE 1
Other techniques for hardware failures in DRAM

| | RAS (row address strobe | |
|---|---|---|
| Category | signal) Feature | Limitations |
| Memory RAS (e.g., | Memory Single Device | Performance |
| indicating DRAM | Data Correction (SDDC) | Negatively |
| Hardware Failure) | ×4 | Impacted |
| | Enhanced Memory | |
| | Double Device Data | |
| | Correction (DDDC + 1) | |
| | ×4 DRAM Adaptive | |
| | Data Correction (ADC), | |
| | single region (SR) | |
| | ×4 DRAM Adaptive | |
| | Double Device Data | |
| | Correction (ADDDC) | |
| | multi region (MR), +1 | |
| | DRAM Rank Sparing | Memory Capacity |
| | DRAM Multi-Rank | Negatively |
| | Sparing | Impacted |
| | DRAM Memory | |
| | Mirroring | |
| | DDR4 Address/partial | |
| | mirroring | |
| | Power up post package | System Reset |
| | repair (PPR) | Required |

As illustrated in Table 1, when a DRAM hardware failure occurs (e.g., detecting and correcting by ECC except mirroring for un-correctable error), the following measures may be taken to resolve the issue: 1) replace the dual in-line memory module (DIMM) with failure, which will typically incur a hardware and service cost; 2) SDDC/DDDC/ADC(SR)/ADDDC(MR) (e.g., as illustrated in Table 1), which will typically have performance impact because memory need to work in lock step mode; 3) memory mirroring and sparing, which will typically reduce the memory capacity and consequently impacts the performance; or 4) power up post package repair, which will typically impact system availability.

In summary, solutions other than runtime post package repair will typically result in hardware and service cost and/or adverse system performance impacts. Conversely, repair of DRAM devices at runtime via runtime post package repair may be performed without system performance and capacity loss, with improved system availability, extended DIMM service time, and/or save costs.

FIG. 3 is an illustration of an example of a procedure 300 to conduct runtime post package repair according to an embodiment. As illustrated, the procedure 300 may involve the runtime DRAM failure detector 102 detecting hardware failures in the DRAM 104. As used herein, the term “runtime” may refer to operations occurring after a BIOS (basic input/output system, e.g., startup program) boot 302 and a handoff to an operating system 304 after the BIOS boot 302 is fully completed. The runtime post package repair handler 106 may correct the detected hardware failures in dynamic random access memory (DRAM) 104. In such an example, the runtime post package repair handler 106 performs such corrections after power up boot operations of BIOS boot 302 have been completed. Conversely, post package repair may often be performed during power up operations (as illustrated below in FIG. 4) as opposed to during runtime operations (as illustrated here in FIG. 3).

For example, some of the implementations described herein may adapt the post package repair procedures defined by the Joint Electron Device Engineering Council (JEDEC) to advantageously permit a runtime repair of DRAM hard failure. For example, fail row address repair may be permitted in DDR4 (double data rate four) memory as an optional feature (e.g., as illustrated in above in FIG. 2), and a post package repair (PPR) that is adapted for runtime operations may provide a procedure to repair the fail row address by the electrical programming of an electrical-fuse scheme. Accordingly, the failure info is collected and saved in the runtime so that repair of the DRAM failure may be performed in runtime. Conversely, the power up-type post package repair failure handling mechanism currently may only be used at reset as a power up-type post package repair.

FIG. 4 is an illustration of a procedure 400 to conduct power up post package repair, which is a different solution for memory repair as compared to the runtime post package repair disclosed herein. As illustrated, the procedure 400 involves power up post package repair 404 (power up PPR) being performed during power up operations as opposed to during runtime operations (as illustrated above in FIG. 3).

For example, power up post package repair 404 may activate only during the Power-On Self-Test (POST) time during BIOS boot 402. For example, Power-On Self-Test (POST) refers to diagnostic testing sequence that is run when power is turned on. The Power-On Self-Test (POST) diagnostic testing sequence is run by BIOS boot 402 (e.g., a computer system basic input/output system or startup program) to determine if the computer keyboard, random access memory, disk drives, and other hardware are working correctly.

After the power up post package repair 404, a Rest of Boot 406 operation may be performed to finish the BIOS boot 402 prior to handing operations off to operating system 408. After operations are handed off to an operating system 408, a DRAM failure detection may be performed on a DRAM 412 during runtime. Usage of this detected error information, however, may necessarily require a system reset with a reboot of BIOS boot 402 in order to utilize the operations of the power up post package repair 404.

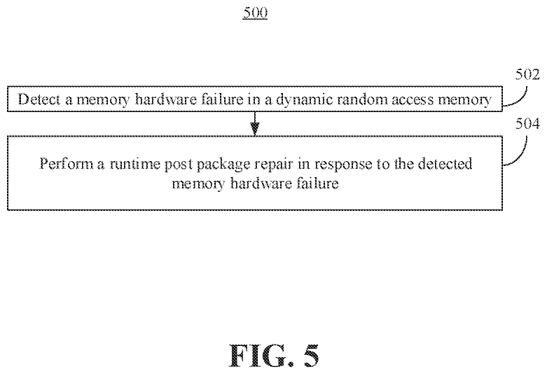

FIG. 5 is a flowchart of an example of a method 500 of conducting runtime memory repair according to an embodiment. As illustrated, the method 500 may be implemented in one or more modules as a set of logic instructions stored in a machine- or computer-readable storage medium such as random access memory (RAM), read only memory (ROM), programmable ROM (PROM), firmware, flash memory, etc., in configurable logic such as, for example, programmable logic arrays (PLAs), field programmable gate arrays (FPGAs), complex programmable logic devices (CPLDs), in fixed-functionality logic hardware using circuit technology such as, for example, application specific integrated circuit (ASIC), complementary metal oxide semiconductor (CMOS) or transistor-transistor logic (TTL) technology, or any combination thereof.

For example, computer program code to carry out operations shown in the method 500 may be written in any combination of one or more programming languages, including an object oriented programming language such as JAVA, SMALLTALK, C++ or the like and conventional procedural programming languages, such as the “C” programming language or similar programming languages. Additionally, logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

Illustrated processing block 502 provides for detecting a memory hardware failure in a dynamic access memory. For example, the detection of the memory hardware failure in a dynamic random access memory may include operations to determine whether the computing system error is a memory error and determine whether the memory error is a hardware failure.

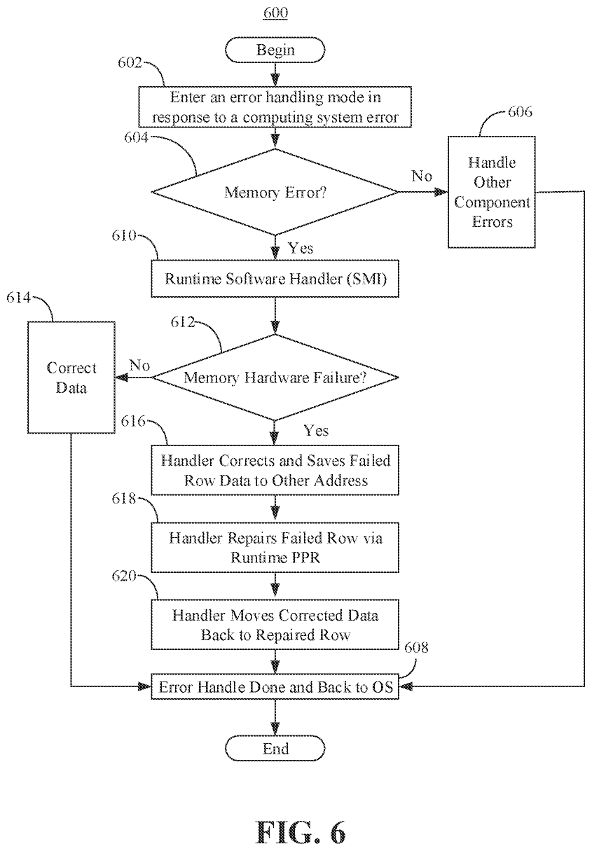

Illustrated processing block 504 provides for performing runtime post package repair in response to the detection of memory hardware failure. For example, the performance of the runtime post package repair may further include operations to correct and save failed row data to one or more other addresses, repair failed row data via post package repair operations, and move the corrected and saved failed row data back to the repaired failed row. Additional and/or alternative details of method 500 are described below with regard to FIG. 6.

FIG. 6 is a more detailed flowchart of an example of a method 600 of repairing runtime memory according to an embodiment. As illustrated, the method 600 may generally be incorporated into blocks 502 and 504 of FIG. 2, already discussed. More particularly, the method 600 may be implemented in one or more modules as a set of logic instructions stored in a machine- or computer-readable storage medium such as RAM, ROM, PROM, firmware, flash memory, etc., in configurable logic such as, for example, PLAs, FPGAs, CPLDs, in fixed-functionality logic hardware using circuit technology such as, for example, ASIC, CMOS or TTL technology, or any combination thereof.

Illustrated processing block 602 enters an error handling mode in response to a computing system error. For example, the detection of the memory hardware failure in a dynamic random access memory may be performed in response to an entry into the to handling mode. In an embodiment, computing system error reports are processed by error handling via firmware System Management Interrupts (SMI). In one example, such computing system error reports are processed in an Enhanced Machine Check Architecture Generation Two (eMCA2) mode, or the like.

For example, System Management Mode (SMM) is a special-purpose operating mode that may provide for handling system-wide functions like power management, system hardware control, and the like. System Management Mode may be used by system firmware, not by application software or general-purpose systems software, to allow for isolated processor environment that operates transparently to the operating system. In an embodiment, SMM imposes certain rules. In general, the System Management Mode can only be entered through System Management Interrupt (SMI) via system firmware in a separate address space that that is inaccessible to other central processing unit modes in order to achieve transparency.

Illustrated processing block 604 a check may be performed to determine whether the computing system error is a memory error or not. For example, the detection of the memory hardware failure in a dynamic random access memory may further include operations to determine whether the computing system error is a memory error.

Illustrated processing block 606 handles other component errors. For example, correction of the computing system error may be performed while bypassing the performance of the runtime post package repair in response to the determination that the computing system error is not a memory error.

Illustrated processing block 608 proceeds processing back to the operating system once the error handling is done. For example, processing may proceed to processing block from any of processing blocks 606, 614, and/or 620.

Illustrated processing block 610 invokes a runtime software handler. For example, a runtime software handler may be invoked in response to a determination that there has been a memory error. The runtime software handler may include operations via System Management Interrupts (SMI).

Illustrated processing block 612 determines whether a memory hardware failure has occurred. For example, the detection of the memory hardware failure in a dynamic random access memory may further include operations to determine whether the memory error is a hardware failure.

Illustrated processing block 614 corrects data associated with the memory error. For example, correction of the computing system error may be performed by correcting the memory error and bypassing the performance of the runtime post package repair in response to the determination that the computing system error is a memory error and the determination that the memory error is not a hardware failure.

Illustrated processing block 616 corrects and saves failed row data to other addresses via the runtime software handler. For example, such operation may be performed as part of the performance of the runtime post package repair. As illustrated the performance of the runtime post package repair may be performed in response to the determination that the computing system error is a memory error and the determination that the memory error is a hardware failure.

Illustrated processing block 618 repairs failed rows via the runtime software handler by implementing a form of post package repair. For example, such operation may be performed as part of the performance of the runtime post package repair.

Illustrated processing block 620 moves the corrected data back to the repaired row via the runtime software handler. For example, such operation may be performed as part of the performance of the runtime post package repair.

In operation runtime post package repair can correct one row per Bank Group of a memory device. Such runtime post package repair may provide a simple and easy repair method in the computer system where Fail Row addresses can be repaired by the electrical programming of an Electrical-fuse scheme. Such runtime post package repair may include some of the same and or similar operations as those described by the Refer to DDR JEDEC Solid State Technology Association specification.

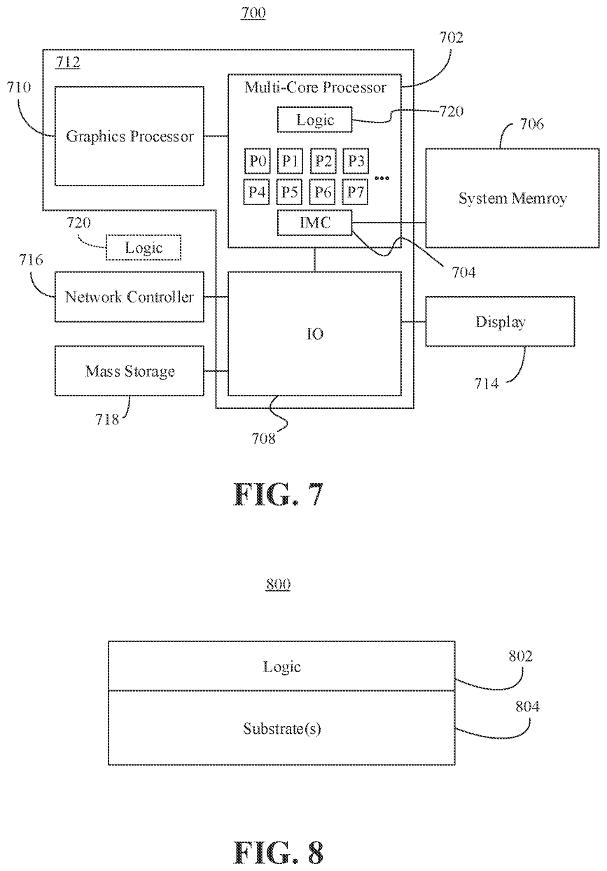

Turning now to FIG. 7, a computing system 700 is shown. The computing system 700 may generally be part of an electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), gaming functionality (e.g., networked multi-player console), etc., or any combination thereof. In the illustrated example, the system 700 includes a multi-core processor 702 (e.g., host processor(s), central processing unit(s)/CPU(s)) having an integrated memory controller (IMC) 704 that is coupled to a system memory 706. The multi-core processor 702 may include a plurality of processor cores P0-P7.

The illustrated system 700 also includes an input output (IO) module 708 implemented together with the multi-core processor 702 and a graphics processor 710 on a semiconductor die 772 as a system on chip (SoC). The illustrated IO module 708 communicates with, for example, a display 714 (e.g., touch screen, liquid crystal display/LCD, light emitting diode/LED display), a network controller 716 (e.g., wired and/or wireless), and mass storage 718 (e.g., hard disk drive/HDD, optical disk, solid state drive/SSD, flash memory).

The multi-core processor 702 may include logic 720 (e.g., logic instructions, configurable logic, fixed-functionality hardware logic, etc., or any combination thereof) to perform one or more aspects of the method 500 (FIG. 5) and/or the method 600 (FIG. 6), already discussed. Although the illustrated logic 720 is located within the multi-core processor 702, the logic 720 may be located elsewhere in the computing system 700.

FIG. 8 shows a semiconductor package apparatus 800. The illustrated apparatus 800 includes one or more substrates 804 (e.g., silicon, sapphire, gallium arsenide) and logic 802 (e.g., transistor array and other integrated circuit/IC components) coupled to the substrate(s) 804. The logic 802 may be implemented at least partly in configurable logic or fixed-functionality logic hardware.

In one example, the logic 802 implements one or more aspects of the method 500 (FIG. 5) and/or the method 600 (FIG. 6) and may be readily substituted for the logic 720 (FIG. 7), already discussed. Thus, the logic 802 may identify a thread and select a core from the plurality of processor cores in response to the selected core being available while satisfying a least used condition with respect to the plurality of processor cores. The logic 802 may also schedule the thread to be executed on the selected core. In one example, the logic 802 tracks active time for the plurality of processor cores and sorts the plurality of processor cores on an active time basis. In one example, the logic 802 includes transistor channel regions that are positioned (e.g., embedded) within the substrate(s) 804. Thus, the interface between the logic 802 and the substrate(s) 804 may not be an abrupt junction. The logic 802 may also be considered to include an epitaxial layer that is grown on an initial wafer of the substrate(s) 804.

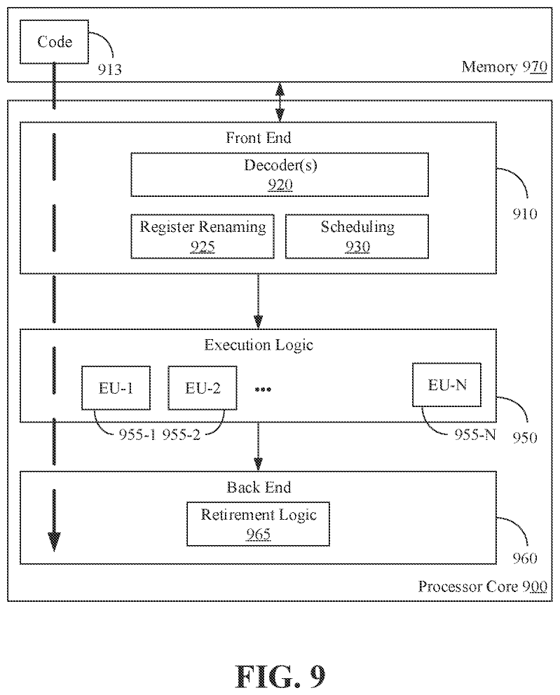

FIG. 9 illustrates a processor core 900 according to one embodiment. The processor core 900 may be the core for any type of processor, such as a micro-processor, an embedded processor, a digital signal processor (DSP), a network processor, or other device to execute code. Although only one processor core 900 is illustrated in FIG. 9, a processing element may alternatively include more than one of the processor core 900 illustrated in FIG. 9. The processor core 900 may be a single-threaded core or, for at least one embodiment, the processor core 900 may be multithreaded in that it may include more than one hardware thread context (or “logical processor”) per core.

FIG. 9 also illustrates a memory 970 coupled to the processor core 900. The memory 970 may be any of a wide variety of memories (including various layers of memory hierarchy) as are known or otherwise available to those of skill in the art. The memory 970 may include one or more code 913 instruction(s) to be executed by the processor core 900, wherein the code 913 may implement one or more aspects of the method 500 (FIG. 5) and/or the method 600 (FIG. 6), already discussed. The processor core 900 follows a program sequence of instructions indicated by the code 913. Each instruction may enter a front end portion 910 and be processed by one or more decoders 920. The decoder 920 may generate as its output a micro operation such as a fixed width micro operation in a predefined format, or may generate other instructions, microinstructions, or control signals which reflect the original code instruction. The illustrated front end portion 910 also includes register renaming logic 925 and scheduling logic 930, which generally allocate resources and queue the operation corresponding to the convert instruction for execution.

The processor core 900 is shown including execution logic 950 having a set of execution units 955-1 through 955-N. Some embodiments may include a number of execution units dedicated to specific functions or sets of functions. Other embodiments may include only one execution unit or one execution unit that can perform a particular function. The illustrated execution logic 950 performs the operations specified by code instructions.

After completion of execution of the operations specified by the code instructions, back end logic 960 retires the instructions of the code 913. In one embodiment, the processor core 900 allows out of order execution but requires in order retirement of instructions. Retirement logic 965 may take a variety of forms as known to those of skill in the art (e.g., re-order buffers or the like). In this manner, the processor core 900 is transformed during execution of the code 913, at least in terms of the output generated by the decoder, the hardware registers and tables utilized by the register renaming logic 925, and any registers (not shown) modified by the execution logic 950.

Although not illustrated in FIG. 9, a processing element may include other elements on chip with the processor core 900. For example, a processing element may include memory control logic along with the processor core 900. The processing element may include I/O control logic and/or may include I/O control logic integrated with memory control logic. The processing element may also include one or more caches.

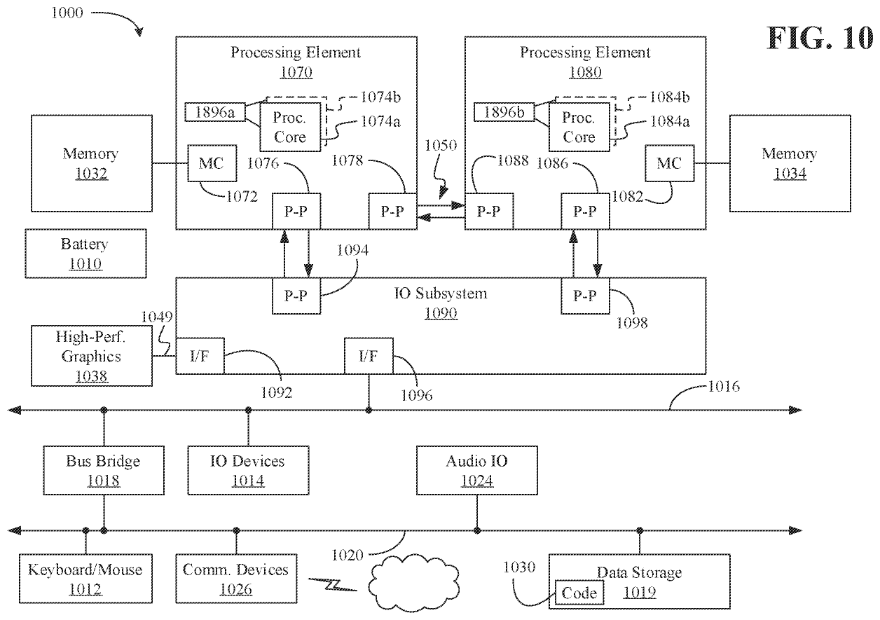

Referring now to FIG. 10, shown is a block diagram of a computing system 1000 embodiment in accordance with an embodiment. Shown in FIG. 10 is a multiprocessor system 1000 that includes a first processing element 1070 and a second processing element 1080. While two processing elements 1070 and 1080 are shown, it is to be understood that an embodiment of the system 1000 may also include only one such processing element.

The system 1000 is illustrated as a point-to-point interconnect system, wherein the first processing element 1070 and the second processing element 1080 are coupled via a point-to-point interconnect 1050. It should be understood that any or all of the interconnects illustrated in FIG. 10 may be implemented as a multi-drop bus rather than point-to-point interconnect.

As shown in FIG. 10, each of processing elements 1070 and 1080 may be multicore processors, including first and second processor cores (i.e., processor cores 1074a and 1074b and processor cores 1084a and 1084b). Such cores 1074a, 1074b, 1084a, 1084b may be configured to execute instruction code in a manner similar to that discussed above in connection with FIG. 9.

Each processing element 1070, 1080 may include at least one shared cache 1896a, 1896b. The shared cache 1896a, 1896b may store data (e.g., instructions) that are utilized by one or more components of the processor, such as the cores 1074a, 1074b and 1084a, 1084b, respectively. For example, the shared cache 1896a, 1896b may locally cache data stored in a memory 1032, 1034 for faster access by components of the processor. In one or more embodiments, the shared cache 1896a, 1896b may include one or more mid-level caches, such as level 2 (L2), level 3 (L3), level 4 (L4), or other levels of cache, a last level cache (LLC), and/or combinations thereof.

While shown with only two processing elements 1070, 1080, it is to be understood that the scope of the embodiments are not so limited. In other embodiments, one or more additional processing elements may be present in a given processor. Alternatively, one or more of processing elements 1070, 1080 may be an element other to than a processor, such as an accelerator or a field programmable gate array. For example, additional processing element(s) may include additional processors(s) that are the same as a first processor 1070, additional processor(s) that are heterogeneous or asymmetric to processor a first processor 1070, accelerators (such as, e.g., graphics accelerators or digital signal processing (DSP) units), field programmable gate arrays, or any other processing element. There can be a variety of differences between the processing elements 1070, 1080 in terms of a spectrum of metrics of merit including architectural, micro architectural, thermal, power consumption characteristics, and the like. These differences may effectively manifest themselves as asymmetry and heterogeneity amongst the processing elements 1070, 1080. For at least one embodiment, the various processing elements 1070, 1080 may reside in the same die package.

The first processing element 1070 may further include memory controller logic (MC) 1072 and point-to-point (P-P) interfaces 1076 and 1078. Similarly, the second processing element 1080 may include a MC 1082 and P-P interfaces 1086 and 1088. As shown in FIG. 10, MC's 1072 and 1082 couple the processors to respective memories, namely a memory 1032 and a memory 1034, which may be portions of main memory locally attached to the respective processors. While the MC 1072 and 1082 is illustrated as integrated into the processing elements 1070, 1080, for alternative embodiments the MC logic may be discrete logic outside the processing elements 1070, 1080 rather than integrated therein.

The first processing element 1070 and the second processing element 1080 may be coupled to an I/O subsystem 1090 via P-P interconnects 1076 1086, respectively. As shown in FIG. 10, the I/O subsystem 1090 includes P-P interfaces 1094 and 1098. Furthermore, I/O subsystem 1090 includes an interface 1092 to couple I/O subsystem 1090 with a high performance graphics engine 1038. In one embodiment, bus 1049 may be used to couple the graphics engine 1038 to the I/O subsystem 1090. Alternately, a point-to-point interconnect may couple these components.

In turn, I/O subsystem 1090 may be coupled to a first bus 1016 via an interface 1096. In one embodiment, the first bus 1016 may be a Peripheral Component Interconnect (PCI) bus, or a bus such as a PCI Express bus or another third generation I/O interconnect bus, although the scope of the embodiments are not so limited.

As shown in FIG. 10, various I/O devices 1014 (e.g., biometric scanners, speakers, cameras, sensors) may be coupled to the first bus 1016, along with a bus to bridge 1018 which may couple the first bus 1016 to a second bus 1020. In one embodiment, the second bus 1020 may be a low pin count (LPC) bus. Various devices may be coupled to the second bus 1020 including, for example, a keyboard/mouse 1012, communication device(s) 1026, and a data storage unit 1019 such as a disk drive or other mass storage device which may include code 1030, in one embodiment.

The illustrated code 1030 may implement one or more aspects of the method 500 (FIG. 5) and/or the method 600 (FIG. 6), already discussed. Further, an audio I/O 1024 may be coupled to second bus 1020 and a battery 1010 may supply power to the computing system 1000.

Note that other embodiments are contemplated. For example, instead of the point-to-point architecture of FIG. 10, a system may implement a multi-drop bus or another such communication topology. Also, the elements of FIG. 10 may alternatively be partitioned using more or fewer integrated chips than shown in FIG. 10.

### ADDITIONAL NOTES AND EXAMPLES

Example 1 includes a computing system for runtime memory repair, the computing system including one or more processors, and a mass storage coupled to the one or more processors, the mass storage including executable program instructions, which when executed by the host processor, cause the computing system to detect a memory hardware failure in a memory, and perform a runtime post package repair in response to the detected memory hardware failure in the memory, where the runtime post package repair is performed after power up boot operations have been completed.

Example 2 includes the computing system of Example 1, where the executable program instructions, when executed by the computing system, cause the computing system to enter an error handling mode in response to a computing system error, and where the detection of the memory hardware failure in the memory is performed in response to the entry into the handling mode.

Example 3 includes the computing system of Example 1, where the detection of the memory hardware failure in the memory further includes operations to determine whether the computing system error is a memory error, determine whether the memory error is a hardware failure, and where the performance of the runtime post package repair is performed in response to the determination that the computing system error is a memory error and the determination that the memory error is a hardware failure.

Example 4 includes the computing system of Example 1, where the performance of the runtime post package repair further includes operations to correct and save failed row data to one or more other addresses, repair failed row via post package repair operations, and move the corrected and saved failed row data back to the repaired failed row.

Example 5 includes the computing system of Example 1, where the executable program instructions, when executed by the computing system, cause the computing system to enter an error handling mode in response to a computing system error, where the memory is a dynamic random access memory, and where the detection of the memory hardware failure in the memory is performed in response to the entry into the handling mode. The detection of the memory hardware failure in the memory further includes operations to determine whether the computing system error is a memory error, determine whether the memory error is a hardware failure, and where the performance of the runtime post package repair is performed in response to the determination that the computing system error is a memory error and the determination that the memory error is a hardware failure. The performance of the runtime post package repair further includes operations to correct and save failed row data to one or more other addresses, repair failed row via post package repair operations, move the corrected and saved failed row data back to the repaired failed row, correct the computing system error and bypassing the performance of the runtime post package repair in response to the determination that the computing system error is not a memory error, and correct the computing system error by correcting the memory error and bypassing the performance of the runtime post package repair in response to the determination that the computing system error is a memory error and the determination that the memory error is not a hardware failure.

Example 6 includes a semiconductor apparatus for runtime memory repair, the semiconductor apparatus including one or more substrates, and logic coupled to the one or more substrates. The logic is implemented at least partly in one or more of configurable logic or fixed-functionality hardware logic, the logic coupled to the one or more substrates to detect a memory hardware failure in a memory, and perform a runtime post package repair in response to the detected memory hardware failure in the memory, where the runtime post package repair is performed after power up boot operations have been completed.

Example 7 includes the semiconductor apparatus of claim 6, where the logic coupled to the one or more substrates is to enter an error handling mode in response to a computing system error, and where the detection of the memory hardware failure in the memory is performed in response to the entry into the handling mode.

Example 8 includes the semiconductor apparatus of claim 6, where the detection of the memory hardware failure in the memory further includes operations to determine whether the computing system error is a memory error, determine whether the memory error is a hardware failure, and where the performance of the runtime post package repair is performed in response to the determination that the computing system error is a memory error and the determination that the memory error is a hardware failure.

Example 9 includes the semiconductor apparatus of claim 6, where the performance of the runtime post package repair further includes operations to correct and save failed row data to one or more other addresses, repair failed row via post package repair operations, and move the corrected and saved failed row data back to the repaired failed row.

Example 10 includes the semiconductor apparatus of claim 6, where the logic coupled to the one or more substrates is to enter an error handling mode in response to a computing system error, where the memory is a dynamic random access memory, and where the detection of the memory hardware failure in the memory is performed in response to the entry into the handling mode. The detection of the memory hardware failure in the memory further includes operations to determine whether the computing system error is a memory error, determine whether the memory error is a hardware failure, and where the performance of the runtime post package repair is performed in response to the determination that the computing system error is a memory error and the determination that the memory error is a hardware failure. The performance of the runtime post package repair further includes operations to correct and save failed row data to one or more other addresses, repair failed row via post package repair operations, move the corrected and saved failed row data back to the repaired failed row, correct the computing system error and bypassing the performance of the runtime post package repair in response to the determination that the computing system error is not a memory error, and correct the computing system error by correcting the memory error and bypassing the performance of the runtime post package repair in response to the determination that the computing system error is a memory error and the determination that the memory error is not a hardware failure.

Example 11 includes the semiconductor apparatus of claim 6, where the logic coupled to the one or more substrates includes transistor channel regions that are positioned within the one or more substrates.

Example 12 includes at least one computer readable storage medium including a set of executable program instructions, which when executed by a computing system, cause the computing system to detect a memory hardware failure in a memory, and perform a runtime post package repair in response to the detected memory hardware failure in the memory, where the runtime post package repair is performed after power up boot operations have been completed.

Example 12 includes the at least one computer readable storage medium of Example 12, where the executable program instructions, when executed by the computing system, cause the computing system to enter an error handling mode in response to a computing system error, and where the detection of the memory hardware failure in the memory is performed in response to the entry into the handling mode.

Example 14 includes the at least one computer readable storage medium of Example 12, where the detection of the memory hardware failure in the memory further includes operations to determine whether the computing system error is a memory error, determine whether the memory error is a hardware failure, and where the performance of the runtime post package repair is performed in response to the determination that the computing system error is a memory error and the determination that the memory error is a hardware failure.

Example 15 includes the at least one computer readable storage medium of Example 12, where the performance of the runtime post package repair further includes operations to correct and save failed row data to one or more other addresses, repair failed row via post package repair operations, and move the corrected and saved failed row data back to the repaired failed row.

Example 16 includes the at least one computer readable storage medium of Example 12, where the executable program instructions, when executed by the computing system, cause the computing system to enter an error handling mode in response to a computing system error, where the memory is a dynamic random access memory, and where the detection of the memory hardware failure in the memory is performed in response to the entry into the handling mode. The detection of the memory hardware failure in the memory further includes operations to determine whether the computing system error is a memory error, determine whether the memory error is a hardware failure, and where the performance of the runtime post package repair is performed in response to the determination that the computing system error is a memory error and the determination that the memory error is a hardware failure. The performance of the runtime post package repair further includes operations to correct and save failed row data to one or more other addresses, repair failed row via post package repair operations, move the corrected and saved failed row data back to the repaired failed row, correct the computing system error and bypassing the performance of the runtime post package repair in response to the determination that the computing system error is not a memory error, and correct the computing system error by correcting the memory error and bypassing the performance of the runtime post package repair in response to the determination that the computing system error is a memory error and the determination that the memory error is not a hardware failure.

Example 17 includes a method of repairing runtime memory, comprising detecting a memory hardware failure in a memory, and performing a runtime post package repair in response to the detected memory hardware failure in the memory, where the runtime post package repair is performed after power up boot operations have been completed.

Example 18 includes the method of claim 17, further including entering an error handling mode in response to a computing system error, and where the detection of the memory hardware failure in the memory is performed in response to the entry into the handling mode.

Example 19 includes the method of claim 17, where the detection of the memory hardware failure in the memory further includes determining whether the computing system error is a memory error, determining whether the memory error is a hardware failure, and where the performance of the runtime post package repair is performed in response to the determination that the computing system error is a memory error and the determination that the memory error is a hardware failure.

Example 20 includes the method of claim 17, where the performance of the runtime post package repair further includes correcting and saving failed row data to one or more other addresses, repairing failed row via post package repair operations, and moving the corrected and saved failed row data back to the repaired failed row.

Example 21 includes the method of claim 17, further including entering an error handling mode in response to a computing system error, where the memory is a dynamic random access memory, and where the detection of the memory hardware failure in the memory is performed in response to the entry into the handling mode. The detection of the memory hardware failure in the memory further includes determining whether the computing system error is a memory error, determining whether the memory error is a hardware failure, and where the performance of the runtime post package repair is performed in response to the determination that the computing system error is a memory error and the determination that the memory error is a hardware failure. The performance of the runtime post package repair further includes correcting and saving failed row data to one or more other addresses, repairing failed row via post package repair operations, moving the corrected and saved failed row data back to the repaired failed row, correcting the computing system error and bypassing the performance of the runtime post package repair in response to the determination that the computing system error is not a memory error, and correcting the computing system error by correcting the memory error and bypassing the performance of the runtime post package repair in response to the determination that the computing system error is a memory error and the determination that the memory error is not a hardware failure.

Example 22 includes means for performing a method as described in any preceding Example.

Example 23 includes machine-readable storage including machine-readable instructions which, when executed, implement a method or realize an apparatus as described in any preceding Example.

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that actually make the logic or processor.

Some embodiments may be implemented, for example, using a machine or tangible computer-readable medium or article which may store an instruction or a set of instructions that, if executed by a machine, may cause the machine to perform a method and/or operations in accordance with the embodiments. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

1-21. (canceled)

22. A computing system comprising:
one or more processors; and
a memory coupled to the one or more processors, the memory including executable program instructions, which when executed by the host processor, cause the computing system to:
detect a memory hardware failure in a dynamic random access memory; and
perform a runtime post package repair in response to the detected memory hardware failure in the dynamic random access memory, wherein the runtime post package repair is done after power up boot operations have been completed.

23. The computing system of claim 22, wherein the executable program instructions, when executed by the computing system, cause the computing system to:
enter an error handling mode in response to a computing system error; and
wherein the detection of the memory hardware failure in a dynamic random access memory is performed in response to the entry into the handling mode.

24. The computing system of claim 22,
wherein the detection of the memory hardware failure in a dynamic random access memory further comprises operations to:
determine whether the computing system error is a memory error;
determine whether the memory error is a hardware failure; and
wherein the performance of the runtime post package repair is performed in response to the determination that the computing system error is a memory error and the determination that the memory error is a hardware failure.

25. The computing system of claim 22, wherein the performance of the runtime post package repair further comprises operations to:
correct and save failed row data to one or more other addresses;
repair failed row via post package repair operations; and
move the corrected and saved failed row data back to the repaired failed row.

26. The computing system of claim 22, wherein the executable program instructions, when executed by the computing system, cause the computing system to:
enter an error handling mode in response to a computing system error;
wherein the detection of the memory hardware failure in a dynamic random access memory is performed in response to the entry into the handling mode;
wherein the detection of the memory hardware failure in a dynamic random access memory further comprises operations to:
determine whether the computing system error is a memory error;
determine whether the memory error is a hardware failure;
wherein the performance of the runtime post package repair is performed in response to the determination that the computing system error is a memory error and the determination that the memory error is a hardware failure;
wherein the performance of the runtime post package repair further comprises operations to:
correct and save failed row data to one or more other addresses;
repair failed row via post package repair operations;
move the corrected and saved failed row data back to the repaired failed row;
correct the computing system error and bypassing the performance of the runtime post package repair in response to the determination that the computing system error is not a memory error; and
correct the computing system error by correcting the memory error and bypassing the performance of the runtime post package repair in response to the determination that the computing system error is a memory error and the determination that the memory error is not a hardware failure.

27. A semiconductor apparatus comprising:
one or more substrates; and
logic coupled to the one or more substrates, wherein the logic is implemented at least partly in one or more of configurable logic or fixed-functionality hardware logic, the logic coupled to the one or more substrates to:
detect a memory hardware failure in a dynamic random access memory; and
perform a runtime post package repair in response to the detected memory hardware failure in the dynamic random access memory, wherein the runtime post package repair is done after power up boot operations have been completed.

28. The semiconductor apparatus of claim 27, wherein the logic coupled to the one or more substrates is to:
enter an error handling mode in response to a computing system error; and
wherein the detection of the memory hardware failure in a dynamic random access memory is performed in response to the entry into the handling mode.

29. The semiconductor apparatus of claim 27,
wherein the detection of the memory hardware failure in a dynamic random access memory further comprises operations to:
determine whether the computing system error is a memory error;
determine whether the memory error is a hardware failure; and
wherein the performance of the runtime post package repair is performed in response to the determination that the computing system error is a memory error and the determination that the memory error is a hardware failure.

30. The semiconductor apparatus of claim 27, wherein the performance of the runtime post package repair further comprises operations to:
correct and save failed row data to one or more other addresses;
repair failed row via post package repair operations; and
move the corrected and saved failed row data back to the repaired failed row.

31. The semiconductor apparatus of claim 27, wherein the logic coupled to the one or more substrates is to:
enter an error handling mode in response to a computing system error;
wherein the detection of the memory hardware failure in a dynamic random access memory is performed in response to the entry into the handling mode;
wherein the detection of the memory hardware failure in a dynamic random access memory further comprises operations to:
determine whether the computing system error is a memory error;
determine whether the memory error is a hardware failure;
wherein the performance of the runtime post package repair is performed in response to the determination that the computing system error is a memory error and the determination that the memory error is a hardware failure;
wherein the performance of the runtime post package repair further comprises operations to:
correct and save failed row data to one or more other addresses;
repair failed row via post package repair operations;
move the corrected and saved failed row data back to the repaired failed row;
correct the computing system error and bypassing the performance of the runtime post package repair in response to the determination that the computing system error is not a memory error; and
correct the computing system error by correcting the memory error and bypassing the performance of the runtime post package repair in response to the determination that the computing system error is a memory error and the determination that the memory error is not a hardware failure.

32. The semiconductor apparatus of claim 28, wherein the logic coupled to the one or more substrates includes transistor channel regions that are positioned within the one or more substrates.

33. At least one computer readable storage medium comprising a set of executable program instructions, which when executed by a computing system, cause the computing system to:
detect a memory hardware failure in a dynamic random access memory; and
perform a runtime post package repair in response to the detected memory hardware failure in the dynamic random access memory, wherein the runtime post package repair is done after power up boot operations have been completed.

34. The at least one computer readable storage medium of claim 33, wherein the executable program instructions, when executed by the computing system, cause the computing system to:
enter an error handling mode in response to a computing system error; and
wherein the detection of the memory hardware failure in a dynamic random access memory is performed in response to the entry into the handling mode.

35. The at least one computer readable storage medium of claim 33,
wherein the detection of the memory hardware failure in a dynamic random access memory further comprises operations to:
determine whether the computing system error is a memory error;
determine whether the memory error is a hardware failure; and
wherein the performance of the runtime post package repair is performed in response to the determination that the computing system error is a memory error and the determination that the memory error is a hardware failure.

36. The at least one computer readable storage medium of claim 33, wherein the performance of the runtime post package repair further comprises operations to:
correct and save failed row data to one or more other addresses;
repair failed row via post package repair operations; and
move the corrected and saved failed row data back to the repaired failed row.

37. The at least one computer readable storage medium of claim 33, wherein the executable program instructions, when executed by the computing system, cause the computing system to:
enter an error handling mode in response to a computing system error;
wherein the detection of the memory hardware failure in a dynamic random access memory is performed in response to the entry into the handling mode;
wherein the detection of the memory hardware failure in a dynamic random access memory further comprises operations to:
determine whether the computing system error is a memory error;
determine whether the memory error is a hardware failure;
wherein the performance of the runtime post package repair is performed in response to the determination that the computing system error is a memory error and the determination that the memory error is a hardware failure;
wherein the performance of the runtime post package repair further comprises operations to:
correct and save failed row data to one or more other addresses;
repair failed row via post package repair operations;
move the corrected and saved failed row data back to the repaired failed row;
correct the computing system error and bypassing the performance of the runtime post package repair in response to the determination that the computing system error is not a memory error; and
correct the computing system error by correcting the memory error and bypassing the performance of the runtime post package repair in response to the determination that the computing system error is a memory error and the determination that the memory error is not a hardware failure.

38. A method comprising:
detecting a memory hardware failure in a dynamic random access memory; and
performing a runtime post package repair in response to the detected memory hardware failure in the dynamic random access memory, wherein the runtime post package repair is done after power up boot operations have been completed.

39. The method of claim 38, further comprising:
entering an error handling mode in response to a computing system error; and
wherein the detection of the memory hardware failure in a dynamic random access memory is performed in response to the entry into the handling mode.

40. The method of claim 38,
wherein the detection of the memory hardware failure in a dynamic random access memory further comprises:
determining whether the computing system error is a memory error;
determining whether the memory error is a hardware failure; and
wherein the performance of the runtime post package repair is performed in response to the determination that the computing system error is a memory error and the determination that the memory error is a hardware failure.

41. The method of claim 38, wherein the performance of the runtime post package repair further comprises:
correcting and saving failed row data to one or more other addresses;
repairing failed row via post package repair operations; and
moving the corrected and saved failed row data back to the repaired failed row.

42. The method of claim 38, further comprising:
entering an error handling mode in response to a computing system error;
wherein the detection of the memory hardware failure in a dynamic random access memory is performed in response to the entry into the handling mode;
wherein the detection of the memory hardware failure in a dynamic random access memory further comprises:
determining whether the computing system error is a memory error;
determining whether the memory error is a hardware failure;
wherein the performance of the runtime post package repair is performed in response to the determination that the computing system error is a memory error and the determination that the memory error is a hardware failure;
wherein the performance of the runtime post package repair further comprises:
correcting and saving failed row data to one or more other addresses;
repairing failed row via post package repair operations;
moving the corrected and saved failed row data back to the repaired failed row;
correcting the computing system error and bypassing the performance of the runtime post package repair in response to the determination that the computing system error is not a memory error; and
correcting the computing system error by correcting the memory error and bypassing the performance of the runtime post package repair in response to the determination that the computing system error is a memory error and the determination that the memory error is not a hardware failure.
